(19) United States
(12) Patent Application Publication
(10) Pub. No.: US 2014/0238578 A1
(43) Pub. Date: Aug. 28, 2014

(54) METHOD FOR MANUFACTURING MONOLITHIC CERAMIC ELECTRONIC COMPONENT

(71) Applicant: Murata Manufacturing Co., Ltd., Nagaokakyo-shi (JP)

(72) Inventor: Masayoshi SHIMIZU, Hachioji-shi (JP)

(73) Assignee: Murata Manufacturing Co., Ltd., Nagaokakyo-shi (JP)

(21) Appl. No.: 14/182,622

(22) Filed: Feb. 18, 2014

(30) Foreign Application Priority Data
Feb. 26, 2013 (JP) 2013-035343

(51) Int. Cl. H01C 17/00; H01G 13/00; H01F 41/04; H01L 41/293

(52) U.S. Cl. CPC H01C 17/006; H01L 41/293; H01G 13/00; H01F 41/04
USPC 156/89.12

(57) ABSTRACT

In a method for manufacturing a monolithic ceramic electronic component, electrically conductive paste layers are formed such that each of the electrically conductive paste layers includes a plurality of electrically conductive paste portions isolated from each other and each of the plurality of electrically conductive paste portions includes a first portion configured to constitute a facing portion and a second portion which includes a portion configured to constitute a lead portion and which is disposed astride a cut line.

### BACKGROUND OF THE INVENTION

1. Field of the Invention

The present invention relates to a method for manufacturing monolithic ceramic electronic component.

2. Description of the Related Art

Demands for miniaturization of monolithic ceramic electronic components, reduction in mounting interval of monolithic ceramic electronic components, and the like have become intensified along with, for example, miniaturization of mobile electronic equipment in recent years. For example, Japanese Unexamined Patent Application Publication No. 10-289837 proposes a monolithic ceramic electronic component, wherein miniaturization is possible so as to reduce a mounting interval. In the monolithic ceramic electronic component described in Japanese Unexamined Patent Application Publication No. 10-289837, first inner electrodes and second inner electrodes are disposed alternately and spaced from each other in a ceramic element assembly. Each of the first and second inner electrodes is led to one surface of the ceramic element assembly. Specifically, the first inner electrodes are led to one side of one surface of the ceramic element assembly and the second inner electrodes are led to the other side of the one surface.

In general, a monolithic ceramic electronic component is produced by preparing a mother laminate and, thereafter, dividing the mother laminate into a plurality of parts from the viewpoint of reduction in the production cost.

The present inventors performed intensive research and, as a result, discovered that when the monolithic ceramic electronic component described in Japanese Unexamined Patent Application Publication No. 10-289837 was produced by this method, peeling of a ceramic layer was caused or a structural defect was caused in some cases.

### SUMMARY OF THE INVENTION

Accordingly, preferred embodiments of the present invention provide a method for manufacturing a monolithic ceramic electronic component, wherein peeling and a structural defect are not caused easily and are significantly decreased or prevented.

A method for manufacturing a monolithic ceramic electronic component, according to various preferred embodiments of the present invention, relates to a method for manufacturing a monolithic ceramic electronic component provided with a substantially rectangular parallelepiped ceramic element assembly and first and second inner electrodes which are disposed in the inside of the ceramic element assembly while facing each other with a ceramic layer therebetween and each of which includes a facing portion arranged to face other facing portion and a lead portion connected to the facing portion and extending to one surface of the ceramic element assembly. In the method for manufacturing a monolithic ceramic electronic component, according to various preferred embodiments of the present invention, ceramic green sheets provided with an electrically conductive paste layer configured to constitute the first or second inner electrode on the surface are prepared. A mother laminate is produced by stacking and pressing the ceramic green sheets. A green chip is prepared by dividing the mother laminate into a plurality of parts along cut lines. The ceramic element assembly provided with the first and second inner electrodes in the inside is produced by firing the green chip. The electrically conductive paste layer is formed in such a way that the electrically conductive paste layer includes a plurality of electrically conductive paste portions isolated from each other and each of the plurality of electrically conductive paste portions includes a first portion configured to constitute the facing portion and a second portion which includes a portion configured to constitute the lead portion and which is disposed astride the cut line.

In an aspect of the method for manufacturing a monolithic ceramic electronic component, according to various preferred embodiments of the present invention, the mother laminate is produced in such a way that portions in which the ceramic green sheets adhere to each other without interposing the electrically conductive paste layer therebetween are disposed continuously in the mother laminate.

In another aspect of the method for manufacturing a monolithic ceramic electronic component, according to various preferred embodiments of the present invention, the electrically conductive paste layer is formed in such a way that a plurality of pairs of two electrically conductive paste portions having point symmetry are arranged in the matrix.

In another aspect of the method for manufacturing a monolithic ceramic electronic component, according to various preferred embodiments of the present invention, each electrically conductive paste portion preferably is formed to be L-shaped or substantially L-shaped.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic perspective view of a monolithic ceramic electronic component produced according to a preferred embodiment of the present invention.

FIG. 2 is a schematic sectional view of a monolithic ceramic electronic component produced according to a preferred embodiment of the present invention.

FIG. 3 is a schematic sectional view of a monolithic ceramic electronic component produced according to a preferred embodiment of the present invention.

FIG. 4 is a schematic sectional view of a section taken along a line IV-IV shown in FIG. 1.

FIG. 5 is a schematic plan view of a first ceramic green sheet.

FIG. 6 is a schematic plan view of a second ceramic green sheet.

FIG. 7 is a schematic sectional view of a mother laminate produced according to a preferred embodiment of the present invention.

FIG. 8 is a schematic perspective view of a green chip produced according to a preferred embodiment of the present invention.

FIG. 9 is a schematic sectional view of a mother laminate produced according to a first reference example.

FIG. 10 is a schematic sectional view of a mother laminate produced according to a second reference example.

### DETAILED DESCRIPTION OF THE PREFERRED EMBODIMENTS

Examples of preferred embodiments according to the present invention will be described below. However, the following preferred embodiments are no more than exemplifications. The present invention is not limited to the following preferred embodiments.

In the drawings referred to in the preferred embodiments and the like, members having the same or substantially the same function are indicated by the same reference numeral. The drawings referred to in the preferred embodiments and the like are schematic diagrams. Ratios and the like of the dimensions of materials drawn in the drawings may be different from the ratios and the like of the dimensions of actual materials. The dimension ratios and the like of materials may be different on a drawing basis. Specific dimension ratios and the like of materials may be estimated in consideration of the following explanations.

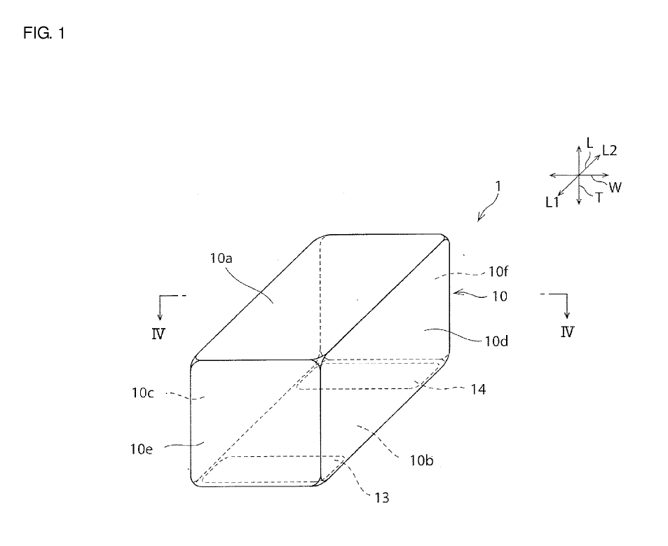

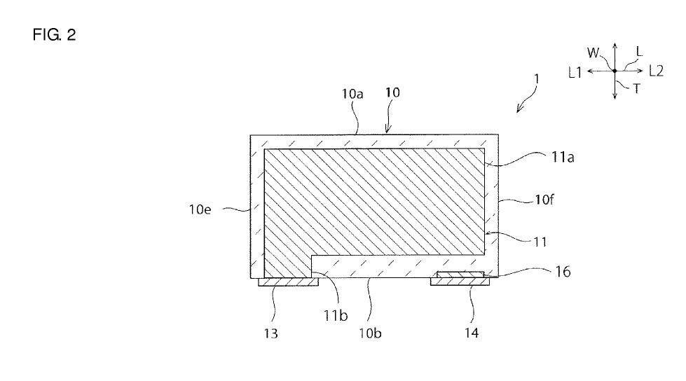

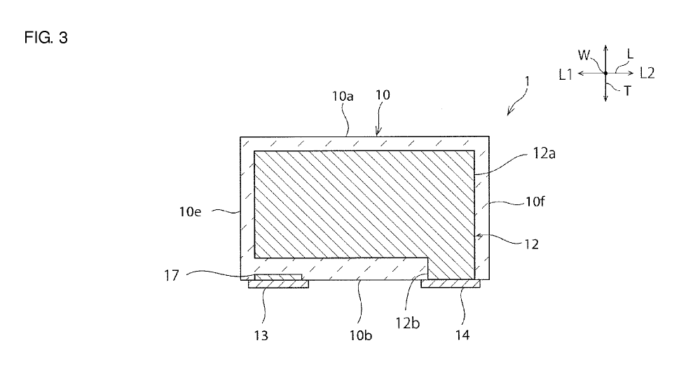

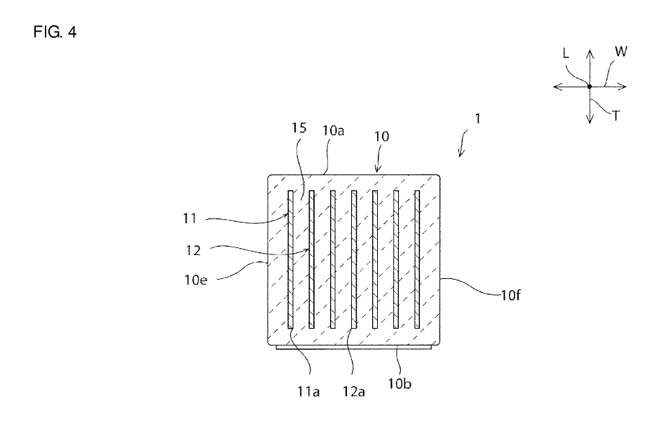

FIG. 1 is a schematic perspective view of a monolithic ceramic electronic component produced according to the present preferred embodiment. Each of FIG. 2 and FIG. 3 is a schematic sectional view of the monolithic ceramic electronic component produced according to the present preferred embodiment. FIG. 4 is a schematic sectional view of a section taken along a line IV-IV shown in FIG. 1.

As shown in FIG. 1 to FIG. 4, a monolithic ceramic electronic component 1 is provided with a ceramic element assembly 10. The ceramic element assembly 10 is preferably formed into the shape of a substantially rectangular parallelepiped, for example. The ceramic element assembly 10 includes first and second principal surfaces 10a and 10b facing each other, first and second side surfaces 10c and 10d facing each other, and first and second end surfaces 10e and 10f facing each other. Each of the first and second principal surfaces 10a and 10b is extended along the length direction L and the width direction W. Each of the first and second side surfaces 10c and 10d is extended along the length direction L and the thickness direction T. Each of the first and second end surfaces 10e and 10f is extended along the width direction W and the thickness direction T. The length direction L and the width direction W are perpendicular to each other. The thickness direction T is perpendicular to each of the length direction L and the width direction W.

In the preferred embodiments of the present invention, the term “rectangular parallelepiped” includes a substantially rectangular parallelepiped in which corner portions and ridge portions are chamfered or R-chamfered. That is, the ceramic element assembly 10 may have a substantially rectangular parallelepiped shape in which at least a portion of corner portions and ridge portions are rounded.

The ceramic element assembly 10 is made from an appropriate ceramic material. The ceramic material constituting the ceramic element assembly 10 is appropriately selected in accordance with the characteristics and the like of the monolithic ceramic electronic component 1.

For example, in the case where the monolithic ceramic electronic component 1 is a ceramic capacitor element, the ceramic element assembly 10 may be made from a material containing dielectric ceramic as a primary component. Specific examples of dielectric ceramic include BaTiO₃, CaTiO₃, SrTiO₃, and CaZrO₃. Accessory components, e.g., Mn compounds, Fe compounds, Cr compounds, Co compounds, and Ni compounds may be added to the ceramic element assembly 10 appropriately.

For example, in the case where the monolithic ceramic electronic component 1 is a ceramic piezoelectric element, the ceramic element assembly 10 may be made from a material containing, for example, piezoelectric ceramic as a primary component. Specific examples of piezoelectric ceramic include lead zirconate titanate (PZT) based ceramic.

For example, in the case where the monolithic ceramic electronic component 1 is a thermistor element, the ceramic element assembly 10 may be made from, for example, semiconductor ceramic. Specific examples of semiconductor ceramic include spinel based ceramic.

For example, in the case where the monolithic ceramic electronic component 1 is an inductor element, the ceramic element assembly 10 may be made from magnetic ceramic. Specific examples of magnetic ceramic include ferrite ceramic.

In the present preferred embodiment, an example in which the monolithic ceramic electronic component 1 is a ceramic capacitor and the ceramic element assembly 10 is made from a material containing dielectric ceramic as a primary component will be described below.

As shown in FIG. 4, a plurality of first inner electrodes 11 and a plurality of second inner electrodes 12 are disposed in the inside of the ceramic element assembly 10. Each of the first and second inner electrodes 11 and 12 is disposed along the length direction L and the thickness direction T in the inside of the ceramic element assembly 10. The first and second inner electrodes 11 and 12 are arranged alternately along the width direction W. Portions of the first and second inner electrodes 11 and 12 face each other with a ceramic layer 15 therebetween in the width direction W. The thickness of the ceramic layer 15 is preferably about 0.3 μm to about 10 μm, for example.

As shown in FIG. 2, the first inner electrode 11 includes a facing portion 11a and a lead portion 11b. As shown in FIG. 3, the second inner electrode 12 includes a facing portion 12b and a lead portion 12b. As shown in FIG. 4, the facing portion 11a and the facing portion 12a face each other in the width direction. As shown in FIG. 2, the lead portion 11b is connected to the facing portion 11a and is led to the second principal surface 10b. Specifically, the lead portion 11b is connected to the L1-side end portion of the facing portion 11a. As shown in FIG. 3, the lead portion 12b is connected to the facing portion 12a and is led to the second principal surface 10b. Specifically, the lead portion 12b is connected to the L2-side end portion of the facing portion 12a.

The thickness of each of the first and second inner electrodes 11 and 12 is preferably about 0.2 μm to about 2.0 μm, for example.

The first and second inner electrodes 11 and 12 are not specifically limited insofar as the electrical conductivity is provided. The first and second inner electrodes 11 and 12 may be made from metals, e.g., Ni, Cu, Ag, Pd, and Au, and alloys, e.g., Ag—Pd alloys, containing at least one type of these metals.

First and second outer electrodes 13 and 14 are disposed on the second principal surface 10b of the ceramic element assembly 10. The first outer electrode 13 is disposed on the L1-side portion of the second principal surface 10b so as to cover an exposed portion of the lead portion 11b of the first inner electrode 11. The first outer electrode 13 is connected to the first inner electrode 11.

The second outer electrode 14 is disposed on the L2-side portion of the second principal surface 10b in such a way as to cover an exposed portion of the lead portion 12b of the second inner electrode 12. The second outer electrode 14 is connected to the second inner electrode 12.

The first and second outer electrodes 13 and 14 may be made from an appropriate electrically conductive material. Each of the first and second outer electrodes 13 and 14 may be a laminate of a plurality of electrically conductive layers.

For example, the outer electrodes 13 and 14 may include base electrode layers disposed so as to cover exposed portions of the lead portions 11b and 12b of the inner electrodes 11 and 12 and plating layers disposed so as to cover the base electrode layers. In that case, the base electrode layers are disposed on the second principal surface 10b of the ceramic element assembly 10 so as to cover the exposed portions of the lead portions 11b and 12b. Preferably, the outer electrodes 13 and 14 do not extend off the second principal surface 10b nor are disposed on the first and second side surfaces 10c and 10d, the first and second end surfaces 10e and 10f, and the first principal surface 10a. The base electrode layers also have a function of sealing the exposed portion of the lead portions 11b and 12b.

The base electrode layer may be formed by baking of an electrically conductive paste film, or be formed by plating. In the case where the base electrode layer is formed by baking of the electrically conductive paste film, it is preferable that the electrically conductive paste layer be formed by using a paste containing an electrically conductive metal and a glass component. In the case where the base electrode layer contains the glass component, the glass component contained in the base electrode layer is located at the interface between the ceramic element assembly 10 and the base electrode layer, the sealing performance of the base electrode layer and the ceramic element assembly is improved, and the fixing strength between the base electrode layer and the ceramic element assembly is enhanced. Examples of preferably usable glass components include glass containing B, Si, Ba, Mg, Al, Li, Zn, or the like. Examples of preferably usable electrically conductive metals include Cu, Ni, Ag, Pd, Ag—Pd alloys, and Au. The base electrode layer may be produced by co-fire in which co-firing with the inner electrodes 11 and 12 is performed or be produced by post-fire in which the electrically conductive paste is applied and baked. In the case where the base electrode layer is produced by baking of the electrically conductive paste layer, the thickness of the base electrode layer is preferably about 10 μm to about 50 μm, for example.

Alternatively, the base electrode layer may be formed by curing an electrically conductive resin containing a thermosetting resin.

The base electrode layer may be formed from a plating film. In that case, the plating film may be made from, for example, at least one type selected from the group consisting of Cu, Ni, Sn, Pb, Au, Ag, Pd, Bi, and Zn. Preferably, the plating layer constituting the base electrode layer (hereafter referred to as “undercoat layer”) does not contain a glass component. The proportion of the metal per unit volume of the undercoat layer is preferably about 99 percent by volume or more, for example. For example, in the case where the inner electrodes 11 and 12 are made from Ni, the undercoat layer is preferably formed from a Cu plating film exhibiting good bondability to Ni. Preferably, the thickness of the undercoat layer is, for example, about 1 μm to about 15 μm.

Preferably, the plating layer disposed on the base electrode layer contains, for example, at least one type selected from the group consisting of Cu, Ni, Sn, Pb, Au, Ag, Pd, Bi, and Zn. The plating layer may be formed from a laminate of a plurality of plating layers. For example, a laminate of a Ni plating film and a Sn plating film may be disposed on the base electrode layer. The Ni plating film delivers solder barrier performance and the Sn plating film enhances the wettability. The thickness of the plating film is preferably about 1 μm to about 10 μm per layer, for example. An electrically conductive resin layer for stress relaxation may be disposed between the base electrode layer and the plating layer.

Dummy conductors 16 and 17 are further disposed in the inside of the ceramic element assembly 10. The dummy conductor 16 is disposed at the same position (same layer) as the position of the first inner electrode 11 in the width direction W. The dummy conductor 16 faces the lead portion 12b in the width direction W. The dummy conductor 16 is not connected to the first inner electrode 11. The dummy conductor 16 is connected to the second outer electrode 14.

The dummy conductor 17 is disposed at the same position (same layer) as the position of the second inner electrode 12 in the width direction W. The dummy conductor 17 faces the lead portion 11b in the width direction W. The dummy conductor 17 is not connected to the second inner electrode 12. The dummy conductor 17 is connected to the first outer electrode 13.

For example, in the case where the first and second outer electrodes 13 and 14 are formed by plating, the dummy conductors 16 and 17 are allowed to serve as nuclei of plating film formation by disposition of the dummy conductors 16 and 17. Therefore, the adhesion strength of the first and second outer electrodes 13 and 14 to the ceramic element assembly 10 may be enhanced.

The dummy conductors 16 and 17 may be made from substantially the same material as the material for the first and second inner electrodes 11 and 12.

The monolithic ceramic electronic component 1 may be produced in the following manner, for example.

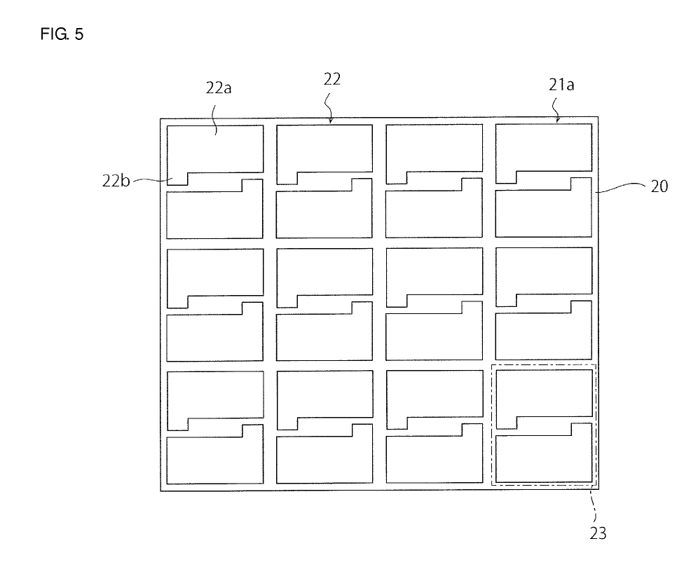

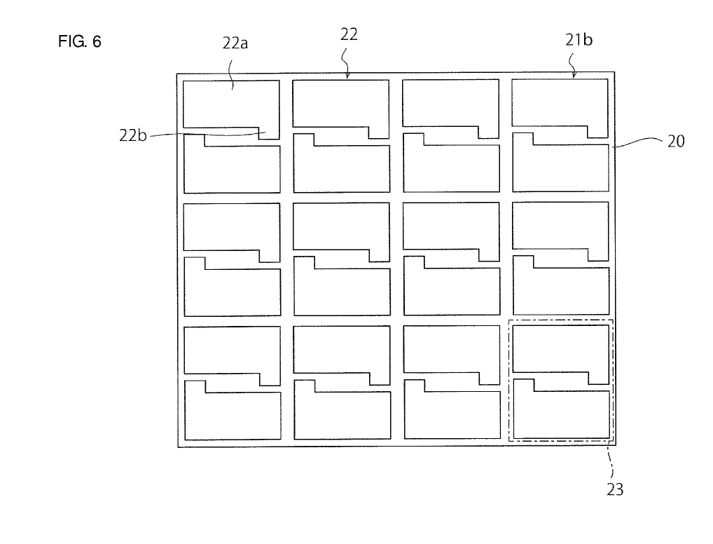

Ceramic green sheets 20 (refer to FIG. 5 and FIG. 6) configured to form the ceramic element assembly 10 are prepared. The ceramic green sheet 20 may be formed by various printing methods, e.g., a screen printing method.

As shown in FIG. 5 and FIG. 6, electrically conductive paste layers 21a and 21b are formed by printing an electrically conductive paste on the ceramic green sheets 20. In this manner, the ceramic green sheet 20 provided with the electrically conductive paste layer 21a configured to form the first inner electrode 11 on the surface (refer to FIG. 5) and the ceramic green sheet 20 provided with the electrically conductive paste layer 21b configured to form the second inner electrode 12 on the surface (refer to FIG. 6) are prepared. Printing of the electrically conductive paste layers 21a and 21b may be performed by the screen printing method or the like. The paste used for printing of the electrically conductive paste layers 21a and 21b may contain an organic binder and an organic solvent in addition to electrically conductive fine particles.

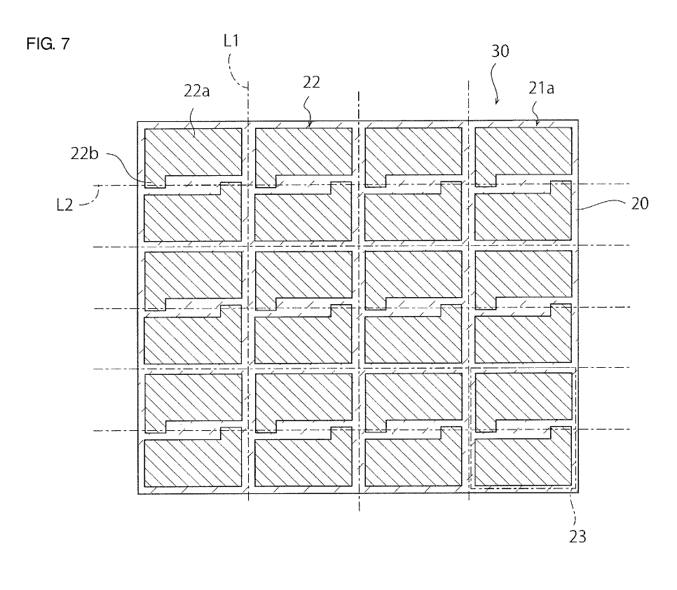

A plurality of ceramic green sheets 20 configured to form an outside layer portion, where electrically conductive paste layer is not printed, are stacked, and ceramic green sheets provided with the electrically conductive paste layer 21a configured to form the first inner electrode 11 on the surface and ceramic green sheets 20 provided with the electrically conductive paste layer 21b configured to form the second inner electrode 12 on the surface are stacked alternately thereon. A plurality of ceramic green sheets 20 configured to form an outside layer portion, where electrically conductive paste layer is not printed, are further stacked thereon. The resulting laminate is pressed by using an isostatic pressing device or the like and, thus, a mother laminate 30 shown in FIG. 7 is produced.

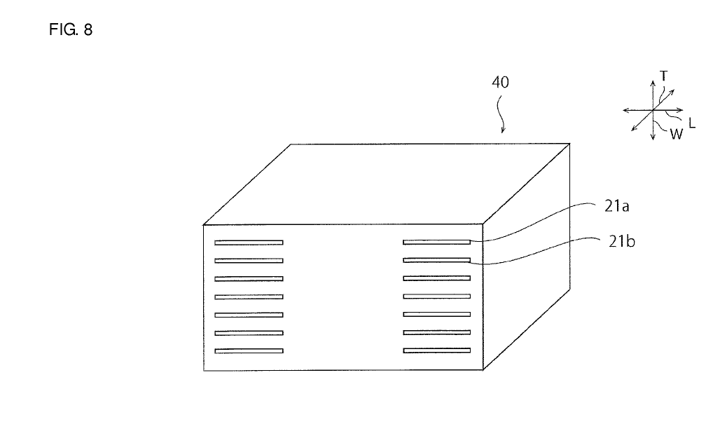

The mother laminate 30 is divided into a plurality of individual components by cutting along cut lines L1 and L2. In this manner, a green chip 40 shown in FIG. 8 is obtained. The chip 40 may be subjected to barrel polishing or the like so as to have the shape in which corner portions and ridge portions are rounded.

The chip 40 is fired and, thus, the ceramic element assembly 10 including the first and the second inner electrodes 11 and 12 is obtained. The firing temperature may be set appropriately in accordance with the composition and the like of the chip 40. The firing temperature may be specified to be, for example, about 900° C. to about 1,300° C.

The first and second outer electrodes 13 and 14 are formed on the second principal surface 10b of the ceramic element assembly 10, so that the monolithic ceramic electronic component 1 is completed. The first and second outer electrodes 13 and 14 may be formed by, for example, plating.

In the present preferred embodiment, not only the inner electrodes 11 and 12 but also the dummy conductors 16 and 17 are exposed at the second principal surface 10b. Therefore, for example, the outer electrodes 13 and 14 in which the base electrode layers are formed from plating layers may be formed easily with a high fixing strength.

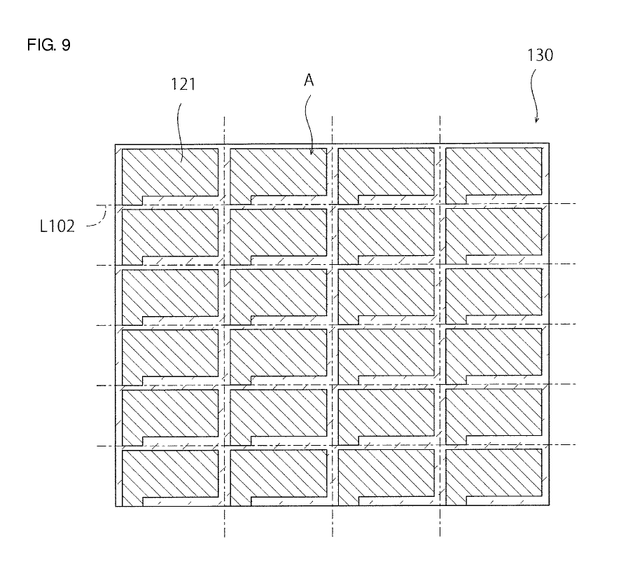

In the case where the chip is formed by producing and dividing the mother laminate, as shown in FIG. 9, it is considered that an electrically conductive paste portion 121 configured to constitute the first or second inner electrode is formed independently in a region A constituting each chip. However, in this case, if the cut position of the mother laminate 130 deviates from the cut line L102, the electrically conductive paste portion 121 is not exposed at the surface of the chip. Consequently, some inner electrodes not connected to the outer electrode may be caused.

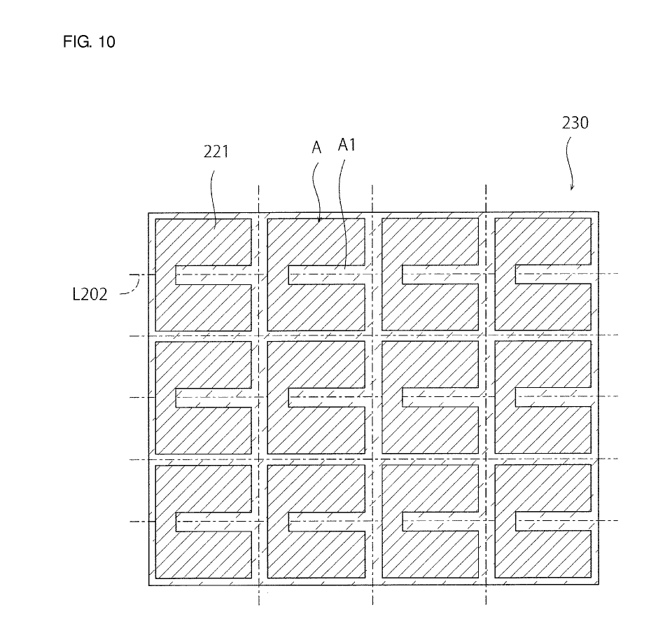

In view of this, it is considered that, for example, as with a mother laminate 230 shown in FIG. 10, portions configured to form lead portions of electrically conductive paste portions 221 disposed in adjacent regions A are formed astride a cut line L202. Consequently, even when the cut position of the mother laminate 230 is deviated from the cut line L202, the electrically conductive paste portion 221 is exposed at the surface of the chip reliably.

However, actual production of the mother laminate 230 shown in FIG. 10 revealed that peeling and a structural defect were caused easily. The reason for this was considered as described below. The portions configured to form lead portions of electrically conductive paste portions 221 are connected and, thus, a region A1 is surrounded on three sides by the electrically conductive paste portion 221. In this region A1, a continuous fluidization path of the ceramic green sheets in pressing of the mother laminate 230 is not ensured and the ceramic green sheets do not fluidize sufficiently. As a result, the adhesion between adjacent ceramic green sheets is reduced and peeling and a structural defect are caused easily.

In the present preferred embodiment, as shown in FIG. 5 to FIG. 7, the electrically conductive paste layers 21a and 21b are formed from a plurality of electrically conductive paste portions 22 which are isolated from each other and which are discontinuous. Accordingly, portions in which the ceramic green sheets 20 adhere to each other without interposing the electrically conductive paste layers 21a and 21b therebetween are allowed to become continuous in the mother laminate 30. Consequently, a continuous fluidization path of the ceramic green sheets 20 in pressing of the mother laminate 30 is ensured and the ceramic green sheets 20 fluidize sufficiently. As a result, peeling, a structural defect, and the like are not caused easily.

In the present preferred embodiment, each of the plurality of electrically conductive paste portions 22 preferably includes a first portion 22a configured to constitute the facing portion 11a or 12a and a second portion 22b configured to constitute the lead portion 11b or 12b. The second portion 22b is disposed astride the cut line L2. Therefore, even when the cut position of the mother laminate 30 is deviated from the cut line L2, the electrically conductive paste portion 22 is exposed at the surface of the chip 40 reliably. Consequently, production of the first inner electrodes 11 not connected to the first outer electrode 13 or the second inner electrodes 12 not connected to the second outer electrode 14 are significantly reduced or prevented.

From the viewpoint of a further improvement in the fluidity of the ceramic green sheet 20, it is preferable that a plurality of pairs 23 of two electrically conductive paste portions 22 disposed so as to have point symmetry be arranged in the matrix. Disposition of two electrically conductive paste portions 22 in such a way as to have point symmetry may improve the symmetry of the pair 23 of the electrically conductive paste portions 22, equalize the fluidization of the ceramic green sheets 20 in pressing as compared with the case where the electrically conductive paste portion has an asymmetric shape, and further reduce or prevent fluidization variations. Consequently, more uniform adhesion is ensured, peeling between the ceramic green sheets 20 or between the ceramic green sheet 20 and the inner electrode 11 or 12 is significantly reduced or prevented, and the advantages of the preferred embodiments of the present invention are more effective.

Furthermore, the plurality of pairs 23 of two electrically conductive paste portions 22 disposed so as to have point symmetry are arranged in the matrix and, thus, around the portions at which the cut lines L1 and L2 are perpendicular or substantially perpendicular to each other as well, the electrically conductive paste layers 21a and 21b are isolated from each other, so that the electrically conductive paste layers 21a and 21b are formed in such a way as to become discontinuous. Conversely, regions not provided with the electrically conductive paste layers 21a and 21b are formed along the cut lines L1 and L2 continuously. In this manner, the fluidization place of the ceramic green sheets 20 in pressing is ensured in whole region of the ceramic green sheets 20 and a difference in the thickness in the stacking direction does not occur. Consequently, more uniform higher adhesion is ensured. Also, peeling between the ceramic green sheets 20 or between the ceramic green sheet 20 and the inner electrode is significantly reduced or prevented and the advantages of the preferred embodiments of the present invention are more effective.

The shape of each electrically conductive paste portion 22 is not specifically limited.

### Experimental Example 1

Eighty ceramic element assemblies having substantially the same configuration as the configuration of the ceramic element assembly 10 of the ceramic electronic component 1 according to the above-described preferred embodiment were produced by the manufacturing method explained in the above-described first preferred embodiment under the following condition.

Predetermined dimension of ceramic capacitor: length: 3.34 to 3.45 mm, width: 1.82 to 1.85 mm, height: 1.84 to 1.86 mm

Material for ceramic element assembly: barium titanate based dielectric ceramic

Primary component of inner electrode: Ni

Inner electrode pattern: patterns shown in FIG. 5 to FIG. 7

Predetermined thickness of inner electrode: 0.68 μm

The total number of inner electrodes: 368 layers

Predetermined thickness of ceramic layer: 3.6 μm

### Experimental Example 2

Eighty ceramic element assemblies were produced as with Example 1 except that the mother laminate having the form shown in FIG. 10 was produced.

The ceramic element assemblies produced in Experimental examples 1 and 2 were immersed into an ink. Thereafter, polishing was performed parallel to the thickness direction T from a second principal surface toward a first principal surface until the lead portions of the first and second inner electrodes were removed so as to expose a cross-section. Whether the ink was impregnated into the facing portions of the plurality of first and second inner electrodes of the cross-section was examined by observation with an optical microscope at a magnification of 200 times or 500 times. A ceramic element assembly in which impregnation with the ink was observed was assumed that peeling between the ceramic green sheets or between the ceramic green sheet and the inner electrode occurred. The results are shown in Table 1 below.

TABLE 1

| | Experimental | Experimental |
|---|---|---|
| | example 1 | example 2 |
| The number of samples in which | 0/80 | 2/80 |
| impregnation with ink | | |
| (peeling) was observed/the | | |
| number of total samples | | |

While preferred embodiments of the invention have been described above, it is to be understood that variations and modifications will be apparent to those skilled in the art without departing from the scope and spirit of the present invention. The scope of the present invention, therefore, is to be determined solely by the following claims.

1. (canceled)

2. A method for manufacturing a monolithic ceramic electronic component including a ceramic element assembly and first and second inner electrodes which are disposed inside of the ceramic element assembly so as to face each other with a ceramic layer therebetween and each of which includes a facing portion configured to face another facing portion and a lead portion connected to the facing portion and extended to one surface of the ceramic element assembly, the method comprising the steps of:
preparing ceramic green sheets provided with an electrically conductive paste layer configured to constitute the first or second inner electrode on the surface;
producing a mother laminate by stacking and pressing the ceramic green sheets;
preparing a green chip by dividing the mother laminate into a plurality of individual components along cut lines; and
producing the ceramic element assembly provided with the first and second inner electrodes inside thereof by firing the green chip; wherein
the electrically conductive paste layer is formed in such a way that the electrically conductive paste layer includes a plurality of electrically conductive paste portions isolated from each other and each of the plurality of electrically conductive paste portions includes a first portion configured to constitute the facing portion and a second portion which includes a portion configured to constitute the lead portion and which is disposed astride the cut line.

3. The method for manufacturing a monolithic ceramic electronic component according to claim 2, wherein the mother laminate is produced in such a way that portions in which the ceramic green sheets adhere to each other without interposing the electrically conductive paste layer therebetween are disposed continuously in the mother laminate.

4. The method for manufacturing a monolithic ceramic electronic component according to claim 2, wherein the electrically conductive paste layer is formed in such a way that a plurality of pairs of two electrically conductive paste portions disposed to have point symmetry are arranged in a matrix.

5. The method for manufacturing a monolithic ceramic electronic component according to claim 2, wherein each electrically conductive paste portion is formed to be L-shaped or substantially L-shaped.

6. The method for manufacturing a monolithic ceramic electronic component according to claim 2, wherein the ceramic element assembly has a rectangular or substantially rectangular parallelepiped shape.

7. The method for manufacturing a monolithic ceramic electronic component according to claim 2, wherein the monolithic ceramic electronic component is one of a ceramic capacitor element, a ceramic piezoelectric element, a thermistor element, and an inductor element.

8. The method for manufacturing a monolithic ceramic electronic component according to claim 2, wherein the ceramic element assembly is formed of one of a material containing dielectric ceramic as a primary component, piezoelectric ceramic as a primary component, a semiconductor ceramic, and a magnetic ceramic.

9. The method for manufacturing a monolithic ceramic electronic component according to claim 2, wherein the ceramic layer has a thickness of about 0.3 μm to about 10 μm.

10. The method for manufacturing a monolithic ceramic electronic component according to claim 2, wherein each of the first and second inner layers has a thickness of about 0.2 μm to about 2.0 μm.

11. The method for manufacturing a monolithic ceramic electronic component according to claim 2, wherein each of the first and second inner layers is formed of at least one of Ni, Cu, Ag, Pd, Au, and an Ag—Pd alloy.

12. The method for manufacturing a monolithic ceramic electronic component according to claim 2, further comprising forming first and second outer electrodes on the ceramic element assembly.

13. The method for manufacturing a monolithic ceramic electronic component according to claim 12, wherein each of the first and second outer electrodes includes a plurality of electrically conductive layers.

14. The method for manufacturing a monolithic ceramic electronic component according to claim 12, wherein each of the first and second outer electrodes includes a base electrode layer that covers the lead portion.

15. The method for manufacturing a monolithic ceramic electronic component according to claim 14, wherein the base electrode layer is formed by plating or baking an electrically conductive film.

16. The method for manufacturing a monolithic ceramic electronic component according to claim 14, wherein the base electrode layer includes a glass component disposed at an interface between the ceramic element assembly and the base electrode layer.

17. The method for manufacturing a monolithic ceramic electronic component according to claim 14, wherein the base electrode layer has a thickness of about 10 μm to about 50 μm.

18. The method for manufacturing a monolithic ceramic electronic component according to claim 14, wherein the base electrode layer has a thickness of about 1 μm to about 15 μm.

19. The method for manufacturing a monolithic ceramic electronic component according to claim 2, further comprising the step of forming dummy conductors inside of the ceramic element assembly.

20. The method for manufacturing a monolithic ceramic electronic component according to claim 19, wherein one of the dummy conductors is disposed on a same layer as the first inner electrode and faces the lead portion in a width direction, and is not connected to the first inner electrode.

21. The method for manufacturing a monolithic ceramic electronic component according to claim 19, wherein one of the dummy conductors is disposed on a same layer as the second inner electrode and faces the lead portion in a width direction, and is not connected to the second inner electrode.
